(19) United States
(12) Patent Application Publication
(10) Pub. No.: US 2015/0214392 A1
(43) Pub. Date: Jul. 30, 2015

(54) PHOTOVOLTAIC CELL HAVING A HETEROJUNCTION AND METHOD FOR MANUFACTURING SUCH A CELL

(71) Applicant: COMMISSARIAT A L'ENERGIE ATOMIQUE ET AUX ENERGIES ALTERNATIVES, Paris (FR)

(72) Inventors: Julien Buckley, Grenoble (FR); Pierre Mur, Crolles (FR)

(73) Assignee: Commissariat à I ' Energie Atomique et aux Energies Alternatives, Paris (FR)

(21) Appl. No.: 14/430,401

(22) PCT Filed: Sep. 24, 2013
(86) PCT No.: PCT/EP2013/069880

§ 371 Date: Mar. 23, 2015

(30) Foreign Application Priority Data
Sep. 24, 2012 (FR) 1258942

(51) Int. Cl. H01L 31/0216; H01L 31/074; H01L 31/18

(52) U.S. Cl. CPC H01L 31/02167; H01L 31/1868; H01L 31/074

(57) ABSTRACT

The invention relates to a photovoltaic cell having a heterojunction, including a doped substrate (1), in which: a first main face (1A) of said substrate is covered with a passivation layer (2A), a doped layer (3A) of the type opposite to the substrate and forming the transmitter of said cell; the second main face (1B) of said substrate is covered with a passivation layer (2B), a doped layer (3B) of the same type as the substrate defining a repulsing field for the minor carriers of the substrate; characterized in that: the material of the passivation layer (2A) on the transmitter (E) side is selected so as to have a lower potential barrier for the photo-generated minor carriers than for the major carrier of the substrate; and in that the material of the passivation layer (2B) on the side of the repulsing field (BSF) is selected so as to have a lower potential barrier for all the photo-generated major carriers than for the minor carriers of the substrate.

### FIELD OF THE INVENTION

The present invention concerns a heterojunction photovoltaic cell and a method for manufacturing said cell.

### BACKGROUND OF THE INVENTION

A heterojunction photovoltaic cell is formed of a stack of layers allowing the direct conversion of received photons into an electrical signal.

Said cell may comprise a doped semiconductor substrate, preferably an n- or p-doped crystalline silicon substrate, and, on either side of said substrate, two semiconductor layers (for example in amorphous or microcrystalline silicon) that are n and p doped or heavily n+ and p+ doped, one of the same electric type as the substrate and the other of opposite type.

The heterojunction is formed by the substrate and the layer with opposite type doping which forms the emitter of the photovoltaic cell.

The cell is intended to be illuminated by the surface comprising the emitter, called the front surface. Said surface is generally texturized and coated with an antireflective layer to minimise reflection of solar radiation.

On the back surface, the layer having the same type of doping as the substrate forms a back repellent electric field known as a “Back Surface Field” (BSF).

The function of this layer is to repel minority carriers of the substrate (i.e. electrons if the substrate is p-doped and holes if the substrate is n-doped) to prevent recombining with the contacts formed on the back surface.

The absorption of a photon by the cell translates as the creation of an electron/hole pair which, under the effect of the intrinsic electrical field generated by the heterojunction, becomes separated so that the photogenerated minority carriers are directed towards the region where these carriers are in majority.

Therefore, in a p-type substrate, the photogenerated electrons are directed towards the emitter of n+ type, whilst the holes are directed towards the back surface field layer of p+ type; in an n-type substrate the photogenerated holes are directed towards the emitter of p+ type whilst the electrons are directed towards the back surface field layer of n+ type.

Electric contacts are formed on the front surface and back surfaces of the cell to collect said photogenerated carriers.

To prevent recombination at the interfaces and to increase the efficacy of conversion, it is usual to intercalate a passivation layer between the substrate and each of the doped or heavily doped layers.

The passivation layer is generally in intrinsic amorphous silicon or a dielectric material, such as an oxide or a nitride.

For example, document FR 2 955 702 discloses a photovoltaic cell in which the front and back passivation layers are in crystalline silicon oxide.

However, the passivation layers form a potential barrier for the carriers and are therefore likely to limit the passing of photogenerated carriers towards the emitter or the back surface field layer where they are to be collected.

Document EP 2 385 561 describes a heterojunction photovoltaic cell in which the passivation layers also allow the passing of carriers via tunnel effect.

Such passivation layers do not however allow optimised collecting of carriers both on the emitter side and on the side of the back surface field layer.

FIG. 1 is a schematic of the band diagram of a cell conforming to document EP 2 385 561.

Underneath the diagram there is schematised the structure of said cell which comprises an n-doped silicon substrate 1, two passivation layers 2A and 2B of silicon oxide (of general formula SiOx), the emitter E comprising a layer 3A of amorphous silicon that is gradually p+ doped and the back surface field BSF comprising a layer 3B of amorphous silicon that is n+ doped.

The conduction band and valence band are respectively designated by the reference signs CB and VB.

The electrons e− are schematised by dark discs whilst the holes h+ are represented by blank discs.

As can be seen in this diagram, on the side of the emitter E, the barrier height is higher for the electrons (φEe) than for the holes (φEh), which promotes passing of the holes via tunnel effect through the passivation layer 2A towards the current collector (not illustrated) of the emitter

On the other hand, on the side of the back surface field BSF, the barrier height is also higher for the electrons (φBe) than for the holes (φBh), which promotes the passing of the holes towards the current collector (not illustrated) of the back surface field. Yet at the back surface field it is sought in priority to collect electrons.

It is one objective of the invention to define an optimal choice of materials for the passivation layers.

### BRIEF DESCRIPTION OF THE INVENTION

For this purpose, there is proposed a heterojunction photovoltaic cell comprising a substrate in doped semiconductor material, wherein:
a first main surface of said substrate is successively coated with a passivation layer, a layer of semiconductor material having opposite doping to the substrate and forming the emitter of said cell, and an electrode;
the second main surface of said substrate is successively coated with a passivation layer, a layer of semiconductor material having the same doping as the substrate and forming a repellent back surface field for the minority carriers of the substrate, and an electrode.

According to the invention:
the material of the passivation layer on the emitter side is selected so as to have a lower potential barrier for the photogenerated minority carriers than for the majority carriers of the substrate, so as to promote the passing of said photogenerated minority carriers from the substrate towards the emitter in relation to the passing of the majority carriers; and
the material of the passivation layer on the back surface field is selected to have a lower potential barrier for the photogenerated majority carriers than for the minority carriers of the substrate, so as to promote the passing of the photogenerated majority carriers from the substrate towards the back surface field layer in relation to the passing of the minority carriers.

Advantageously, the layers forming the emitter and the back surface field are heavily doped.

By “heavily doped” is meant that the doping level of the layer is higher by at least one order of magnitude compared with the doping level of the substrate. The term n+ doping or p+ doping is then used in the event of heavy doping instead of n or p for doping of the same order of magnitude as the substrate doping.

For example, the doping of a so-called “heavily doped” layer may have a dopant concentration higher than 10¹⁷ at·cm⁻³.

The substrate in particular may have a resistivity of between 0.5 and 10 Ω·cm.

According to one embodiment of the invention, the substrate is in n-doped crystalline silicon and the layers respectively p or p+ doped and n or n+ doped are in amorphous or microcrystalline silicon.

In this case, the material of the passivation layer on the emitter side is advantageously selected from nitrided hafnium silicate and silicon nitride, and the material of the passivation layer on the back surface field side is advantageously selected from silicon oxide and tantalum oxide.

According to one alternative embodiment, the substrate is in p-doped crystalline silicon and the n or n+ and p or p+ doped layers are in amorphous or microcrystalline silicon.

In this case, the material of the passivation layer on the emitter side is advantageously selected from silicon oxide and tantalum oxide, and the material of the passivation layer on the back surface field side is advantageously selected from nitrided hafnium silicate and silicon nitride.

Preferably, the thickness of said passivation layers is between 0.1 nm and 5 nm, and more preferably between 0.1 nm and about 1 nm.

According to one particular embodiment of the invention, said cell also comprises a layer of intrinsic amorphous silicon between each passivation layer and the doped amorphous or microcrystalline silicon layer.

Particularly advantageously, at least one surface of said cell is texturized.

A further subject of the invention concerns a method for manufacturing a said cell.

Said method comprises the following steps:

(a) forming, on the first main surface of the substrate, a passivation layer in a material selected to have a lower potential barrier for the photogenerated minority carriers than for the majority carriers of the substrate, so as to promote the passing of said photogenerated minority carriers from the substrate towards the emitter, in relation to the passing of the majority carriers;

(b) forming, on the second main surface of said substrate, a passivation layer in a material selected to have to lower potential barrier for the photogenerated majority carriers than for the minority carriers of the substrate, to promote the passing of said photogenerated majority carriers from the substrate towards the back surface field layer in relation to the passing of the minority carriers.

According to one embodiment of said method, the substrate is in n-doped crystalline silicon and the respective p or p+ and n or n+ doped layers are in amorphous or microcrystalline silicon.

In this case, the passivation layer on the emitter side may be in nitrided hafnium silicate, said layer advantageously being formed by depositing, on the first main surface of the substrate, a layer of hafnium silicate and nitriding said layer.

The passivation layer on the back surface field side may be in silicon oxide, said layer being formed by plasma oxidation of the substrate.

According to another embodiment of the method, the substrate is in p-doped crystalline silicon and the respective n+ and p+ doped layers are in amorphous or microcrystalline silicon.

In this case, the passivation layer on the side of the back surface field (BSF) is advantageously in nitrided hafnium silicate, said layer being formed depositing, on the second main surface of the substrate, a layer of hafnium silicate and nitriding said layer.

The passivation layer on the emitter side may be in silicon oxide, said layer being formed by plasma oxidation of the substrate.

Preferably, the thickness of said passivation layers is between 0.1 nm and 5 nm, and more preferably between 0.1 and about 1 nm.

### BRIEF DESCRIPTION OF THE DRAWINGS

Other characteristics and advantages of the invention will become apparent from the following detailed description with reference to the appended drawings in which:

FIG. 1 is a schematic of the band diagram of a prior art cell (EP 2 385 561);

FIG. 2 is a schematic of a photovoltaic cell according to an embodiment of the invention;

FIG. 3 is a schematic of the band diagram of a cell according to an embodiment of the invention, the substrate being in n-doped silicon;

FIG. 4 is a schematic of the band diagram of a cell which, unlike the invention, comprises passivation layers formed in the same material on the emitter side and on the back surface field layer side, the substrate being in n-doped silicon.

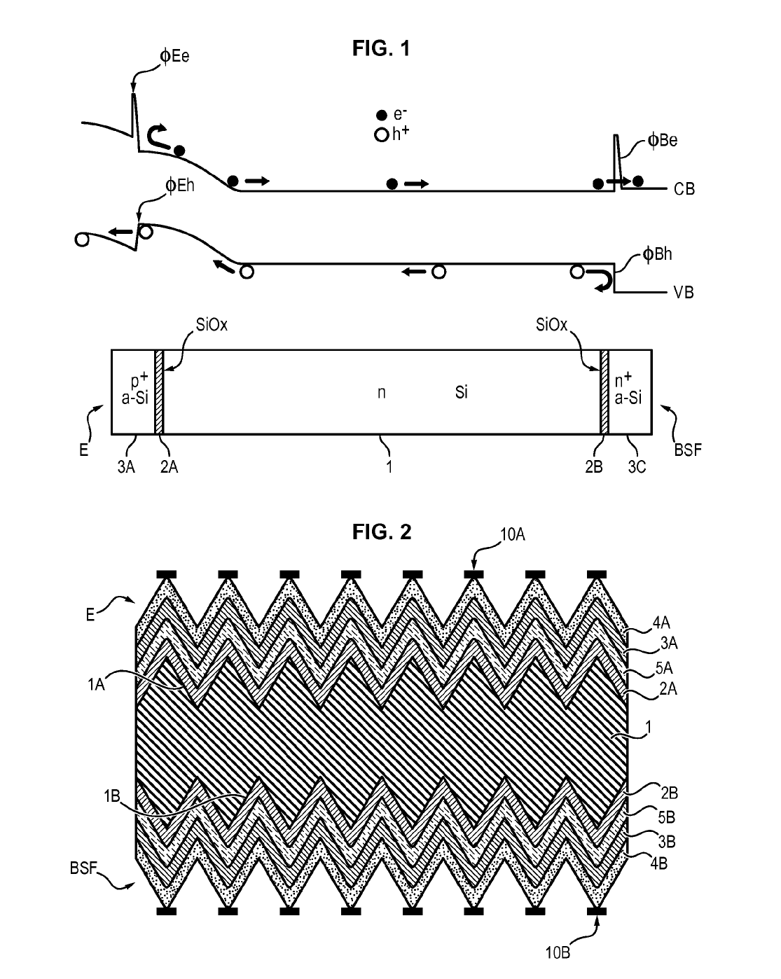

### DETAILED DESCRIPTION OF EMBODIMENTS OF THE INVENTION

FIG. 2 is a cross-sectional view of a photovoltaic cell according to an embodiment of the invention.

The cell comprises a substrate 1 which is in doped semiconductor material, for example doped crystalline silicon.

Alternatively, said substrate may also be in another semiconductor material e.g. Ge, InGaN, GaAs (non-limiting list).

Advantageously the surface of the cell intended to receive solar radiation is texturized to minimise reflections.

In the example illustrated in FIG. 2, the two surfaces of the cell are texturized, the texture being in the form of adjacent pyramids. Nevertheless, neither or only one of the surfaces may be texturized, and the texture may take on any other form without departing from the scope of the invention.

The emitter E of the cell is formed on a first main surface 1A of said substrate.

For this purpose said surface 1A is successively coated with a passivation layer 2A, a layer 3A of doped or heavily doped semiconductor material having opposite type doping to the substrate 1, forming the heterojunction with the substrate 1, and an electrode 4A.

The passivation layer 2A is formed directly on the first main surface 1A of the substrate 1, without any layer of another material being intercalated between the substrate and said layer 2A.

Since layer 2A is in dielectric material, it has the effect of passivating the surface 1A of the substrate 1.

To ensure good quality passivation radical oxidation and/or hydrogenation of the surface of the silicon substrate can be previously performed.

The semiconductor material of the layer 3A is advantageously amorphous or micro crystalline silicon.

Said electrode 4A is typically in indium tin oxide (ITO) which is transparent to solar radiation.

On electrode 4A there is formed a current collector 10A which, in the illustrated embodiment, is in the form of a metal comb.

Optionally, a layer 5A of intrinsic amorphous silicon (i.e. not intentionally doped) can be intercalated between the passivation layer 2A and the doped layer 3A.

Said layer 5A can help improve passivation on the emitter side, in addition to the passivation layer 2A.

The back surface field layer BSF is formed on the second main surface 1B of the substrate.

For this purpose, the second main surface 1B of the substrate is successively coated with a passivation layer 2B, a layer 3B of doped or heavily doped semiconductor material having the same type of doping as the substrate, forming a back surface field BSF for the minority carriers of the substrate, and an electrode 4B.

The passivation layer 2B is formed directly on the first main surface 1A of the substrate 1, without any layer of another material being intercalated between the substrate and said layer 2A.

Since layer 2B is in dielectric material it has the effect of passivating the surface 1B of the substrate 1.

The semiconductor material of layer 3B is advantageously amorphous or microcrystalline silicon.

Said electrode 4B is in indium tin oxide (ITO) for example.

On electrode 4B there is formed a current collector 10B which, in the illustrated embodiment, is in the form of a metal comb.

Optionally, a layer 5B of intrinsic amorphous silicon can be intercalated between the passivation layer 2B and the doped layer 3B.

Said layer 5B can allow improved passivating on the back surface field side as an addition to the passivation layer 2B.

The different layers mentioned above are deposited on each of the surfaces of the substrate 1 using techniques well known to persons skilled in the art.

These layers are deposited with conformity i.e. they are of constant thickness at every point of the surface of the cell. They therefore reproduce the relief imparted by the texture of the substrate surface on which they are deposited.

Said layers can be formed simultaneously on both surfaces of the substrate or else successively on one surface and then on the other.

Contrary to known photovoltaic cells, the passivation layer 2A formed on the emitter side and the passivation layer 2B formed on the side of the back surface field layer are not formed of the same material.

Each of the passivation layers 2A and 2B is in a material selected to allow the collection, at the emitter and at the back surface field layer respectively, of a maximum number of photogenerated carriers in relation to nonphotogenerated carriers.

Depending on the type of doping of the substrate, pairs of different materials are therefore defined for the passivation layer 2A on the emitter side and for the passivation layer 2B on the side of the back surface field.

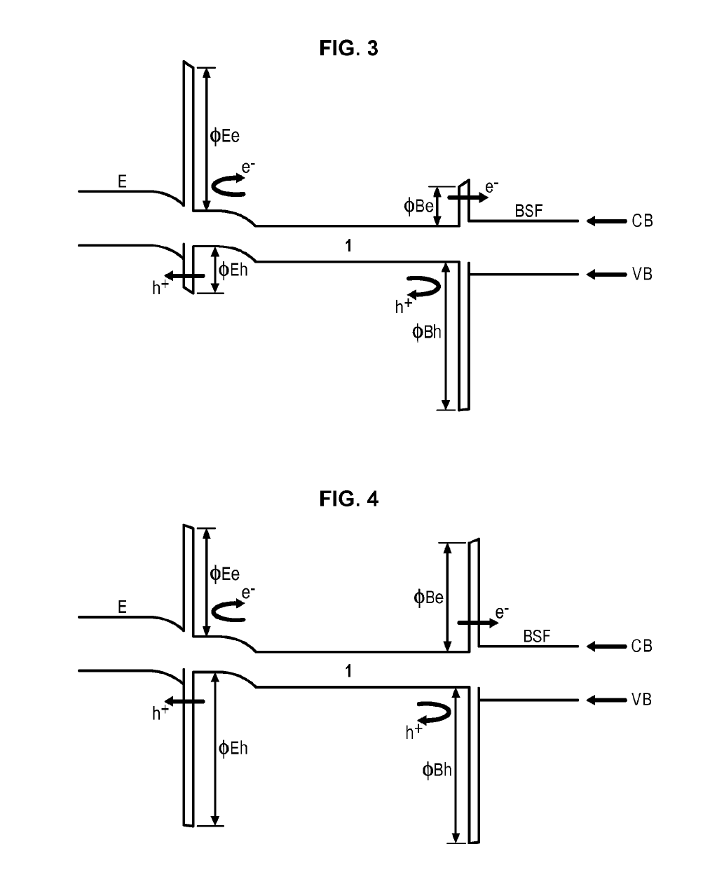

FIG. 3 illustrates a band diagram of a said cell for an n-type substrate. The photogenerated carriers (electrons e− and holes h+ are respectively shown on the conduction band CB and valence band VB).

It is recalled that in an n-type substrate, the photogenerated holes (which correspond to the minority carriers) are directed towards the emitter of p+ type, whilst the photogenerated electrons (which correspond to the majority carriers) are directed towards the back surface field layer of n+ type.

In the diagram in FIG. 3 the following magnitudes are given:

φEe: barrier height for the electrons at the emitter E;

φBe: barrier height for the electrons at the back surface field BSF;

φEh: barrier height for the holes at the emitter;

φBh: barrier height for the holes at the back surface field.

As can be seen in FIG. 3, on the side of the emitter E the barrier height φEe generated by the passivation layer 2A is higher than the barrier height φEh, which results in the fact that the passing of the photogenerated holes towards the current collector 10A is promoted in priority over the passing of the electrons (nonphotogenerated carriers).

On the other hand, on the back surface field BSF side, the barrier height φBe generated by the passivation layer 2B is lower than the barrier height φBh, which results in the fact that the passing of the photogenerated electrons towards the current collector 10B is promoted in priority over the passing of the holes (nonphotogenerated carriers).

Conversely when the substrate is of p-type, the photogenerated electrons (which correspond to the minority carriers) are directed towards the emitter of n+ type whilst the photogenerated holes (which correspond to the majority carriers) are directed towards the back surface field layer of p-type.

In this case, the materials of the passivation layers are selected as follows:
on the emitter side, a passivation layer is selected which generates a barrier height φEe lower than the barrier height φEh, so as to promote the passing of the photogenerated electrons in relation to the passing of the holes towards the current collector 10A;
on the back surface field side a passivation layer is selected which generates a barrier height φBe higher than the barrier height φBh, so as to promote the passing of the photogenerated holes in relation to the passing of the electrons towards the current collector 10B.

The table below gives some examples of pairs of suitable materials depending on the type of substrate doping.

| Type of substrate | Passivation layer | Passivation layer on |
|---|---|---|
| doping | on emitter side | back surface field side |
| n | HfSiON | SiO₂ |
| n | SiN | SiO₂ |
| n | SiN | Ta₂O₅ |
| n | HfSiON | Ta₂O₅ |
| p | SiO₂ | HfSiON |
| p | SiO₂ | SiN |
| p | Ta₂O₅ | HfSiON |
| p | Ta₂O₅ | SiN |

In the event that the substrate is not in silicon but in another semiconductor material, the pairs of materials given in the above table can be used, with the exception of those material pairs comprising silicon oxide.

It is specified that the denotation used for the different envisaged materials is not intended to specify a specific chemical composition including the stoichiometry of the different elements, but to indicate a family of materials containing the indicated elements.

According to an embodiment in which the substrate 1 is of n-type, the passivation layer 2A (on the emitter side) is formed of nitrided hafnium silicate (also denoted HfSiON) and the passivation layer 2B (on the back surface field side) is formed of silicon oxide (also denoted SiO₂ or more generally SiOₓ).

HfSiON has a barrier height in relation to silicon of about 1.6 eV for holes and of 2.1 eV for electrons [Barrett06].

The optimisation of the passivation technique using a layer of HfSiON has been described in [O'Connor09].

The layer 2A can be formed by chemical vapour deposit (CVD) of a layer of hafnium silicate (denoted HfSiO₂) followed by nitriding of said layer at 750° C. with NH₃.

The thickness of said layer is typically between 0.1 and 5 nm and advantageously 1 nm or less.

SiOₓ has a barrier height in relation to silicon of about 3 eV for electrons and higher than 4 eV for holes [Gritsenko03].

The layer 2B can be formed by plasma oxidation of surface 1B of the substrate 1, allowing a silicon oxide to be obtained having a thickness of about 1 nm.

According to an alternative embodiment in which the substrate 1 is also of n-type, the passivation layer 2A (emitter side) is formed of silicon nitride (SiN) and the passivation layer 2B (back surface field side) is formed of SiO₂.

SiN has a barrier height in relation to silicon of about 1.5 eV for holes and 2 eV for electrons [Gritsenko03].

Said SiN layer is advantageously formed by chemical vapour deposit.

According to one embodiment in which the substrate 1 is of p-type, the passivation layer 2A (emitter side) is formed of SiO₂ and the passivation layer 2B (back surface field side) is formed of HfSiON.

According to an alternative embodiment in which the substrate 1 is also of p-type, the passivation layer 2A (emitter side) is formed of SiO₂ and the passivation layer 2B (back field surface side) is formed of SiN.

By way of comparison with the band diagram in FIG. 3, which corresponds to a cell according to the invention, FIG. 4 gives the band diagram of a cell having a stack of layers similar to the cell in FIG. 2 but in which, contrary to the invention, the passivation layers on the emitter side and back surface field side are both in silicon oxide (SiOx).

It can be seen that the barrier heights φEe, φBe for the electrons are higher than the barrier heights φEh, φBh for the holes.

This means that, depending on substrate type, for one of the sides of the cell (emitter or back surface field) the passing of the photogenerated carriers that it is sought to collect is disadvantaged compared with the passing of nonphotogenerated carriers.

### REFERENCES

FR 2 955 702
EP 2 385 561
[Barrett06] “Band offsets of nitrided ultrathin hafnium silicate films”, N. T. Barrett, O. Renault, P. Besson, Y. Le Tiec, and F. Martin, APL 88, 162906, 2006
[Gritsenlo03] “Valence band offset at siliconysilicon nitride and silicon nitrideysilicon oxide interfaces”, Vladimir A. Gritsenko, Alexandr V. Shaposhnikov, W. M. Kwokb, Hei Wongc, Georgii M. Jidomirov, Thin Solid Films 437 (2003) 135-139
[O'Connor09] “The Role of Nitrogen in HfSiON Defect Passivation”, R. O'Connor, M. Aoulaiche, L. Pantisano, A. Shickova, R. Degraeve, B. Kaczer, G. Groeseneken, International Reliability Physics Symposium, pp. 921-924, 2009.

1. A heterojunction photovoltaic cell comprising a substrate in a doped semiconductor material, wherein:
a first main surface of said substrate is successively coated with a passivation layer, a layer of semiconductor material having opposite type doping to the substrate and forming the emitter of the said cell, and an electrode,
the second main surface of said substrate is successively coated with a passivation layer, a layer of semiconductor material having same type doping as the substrate and forming a back surface field for the minority carriers of the substrate, and an electrode,
wherein:
the material of the passivation layer on the emitter side is selected to have a lower potential barrier for the photogenerated minority carriers than for the majority carriers of the substrate, so as to promote the passing of the said photogenerated minority carriers from the substrate towards the emitter in relation to the passing of the majority carriers; and
the material of the passivation layer on the side of the back surface field is selected to have a lower potential barrier for the photogenerated majority carriers than for the minority carriers of the substrate, so as to promote the passing of the photogenerated majority carriers from the substrate towards the back surface field layer in relation to the passing of the minority carriers.

2. The photovoltaic cell of claim 1, wherein the substrate is in n-doped crystalline silicon and the doped layers respectively of p or p+ type and of n or n+ type are in amorphous or microcrystalline silicon.

3. The photovoltaic cell of claim 2, wherein:
the material of the passivation layer on the emitter side is selected from nitrided hafnium silicate and silicon nitride; and
the material of the passivation layer on the back surface field side is selected from silicon oxide and tantalum oxide.

4. The photovoltaic cell of claim 1, wherein the substrate is in p-doped crystalline silicon and the doped layers respectively of n or n+ type and p or p+ type are in amorphous or microcrystalline silicon.

5. The photovoltaic cell of claim 4, wherein:
the material of the passivation layer on the emitter side is selected from silicon oxide and tantalum oxide; and
the material of the passivation layer on the back surface field side is selected from among nitrided hafnium silicate and silicon nitride.

6. The photovoltaic cell of claim 1, wherein the thickness of the passivation layers is between 0.1 nm and 5 nm and is preferably between 0.1 nm and about 1 nm.

7. The photovoltaic cell of claim 2, further comprising between each passivation layer and the layer of doped amorphous or microcrystalline silicon, a layer of intrinsic amorphous silicon.

8. The photovoltaic cell of claim 1, wherein at least one surface of the cell is texturized.

9. A method for manufacturing a heterojunction photovoltaic cell comprising a substrate in a doped semiconductor material, wherein:
a first main surface of said substrate is successively coated with a passivation layer, a layer in semiconductor material having opposite type doping to the substrate and forming the emitter of said cell, and an electrode,
the second main surface of said substrate is successively coated with a passivation layer, a layer in semiconductor material having same type doping as the substrate and forming a back surface field for the minority carriers of the substrate, and an electrode,
the method further comprising the following steps:
forming, on the first main surface of the substrate, a passivation layer in a material selected to have a lower potential barrier for the photogenerated minority carriers than for the majority carriers of the substrate, so as to promote the passing of said photogenerated minority carriers from the substrate towards the emitter in relation to the passing of the majority carriers;
forming, on the second main surface of the substrate, a passivation layer in a material selected to have a lower potential barrier for the photogenerated majority carriers than for the minority carriers of the substrate, so as to promote the passing of the said photogenerated majority carriers from the substrate towards the back surface field layer, in relation to the passing of the minority carriers.

10. The method of claim 9, wherein the substrate is in n-doped crystalline silicon and the layers respectively p or p+ doped and n or n+ doped are in amorphous or microcrystalline silicon.

11. The method of claim 10, wherein the passivation layer on the emitter side is in nitrided hafnium silicate and said layer is formed by depositing, on the first main surface of the substrate, a layer of hafnium silicate and nitriding said layer.

12. The method of claim 10, wherein the passivation layer on the back surface field side is in silicon oxide, said layer being formed by plasma oxidation of the substrate.

13. The method of claim 9, wherein the substrate is in p-doped crystalline silicon and the layers respectively n+ and p+ doped are in amorphous or microcrystalline silicon.

14. The method of claim 13, wherein the passivation layer on the side of the back surface field is in nitrided hafnium silicate and said layer is formed by depositing, on the second main surface of the substrate, a layer of hafnium silicate and nitriding said layer.

15. The method of claim 13, wherein the passivation layer on the emitter side is in silicon oxide, said layer being formed by plasma oxidation of the substrate.

16. The method of claim 9, wherein the thickness of the passivation layers is between 0.1 nm and 5 nm and is preferably between 0.1 and about 1 nm.
